(19) United States
(12) Patent Application Publication
(10) Pub. No.: US 2026/0059784 A1
(43) Pub. Date: Feb. 26, 2026

(54) SEMICONDUCTOR DEVICE

(71) Applicant: Ancora Semiconductors Inc., Taoyuan City (TW)

(72) Inventors: Li-Fan LIN, Taoyuan City (TW); Ying-Chen LIU, Taoyuan City (TW)

(21) Appl. No.: 18/815,803

(22) Filed: Aug. 26, 2024

(51) Int. Cl. H01L 23/00; H01L 23/495; H01L 29/20; H01L 29/40; H01L 29/417; H01L 29/778

(52) U.S. Cl. CPC H01L 24/05; H01L 23/49562; H01L 24/16; H01L 24/48; H10D 30/475; H10D 62/8503; H10D 64/112; H10D 64/257; H01L 2224/05012; H01L 2224/16245; H01L 2224/48245; H01L 2924/1033; H01L 2924/13064; H01L 2924/30101; H01L 2924/30105

(57) ABSTRACT

A semiconductor device includes an active layer having an active region, a source electrode and a drain electrode disposed on the active region of the active layer and extending along a first direction, a source metal layer disposed on the active region and electrically connected to the source electrode, a drain metal layer disposed on the active region and electrically connected to the drain electrode, and a source pad disposed on the active region. The source metal layer extends along a first direction and has a trapezoid shape in a plan view. The drain metal layer extends along the first direction and has a trapezoid shape in the plan view. The source pad is electrically connected to the source metal layer, and the source pad includes a body portion extending along a second direction and a branch portion extending along the first direction.

### BACKGROUND

### Field of Disclosure

The present disclosure relates to a semiconductor device.

### Description of Related Art

For a semiconductor device, the parasitic on-state resistance caused by the metal layers and the wires and the capacitance between the metal layers are crucial to the electrical performance. For example, when the overlapping area between the source/drain pad and the source/drain metal layers, the capacitance formed therebetween become larger and the metal parasitic on-state resistance increases. The wire parasitic on-state resistance increases when the number of the wires increases. Thus, there is a need to provide a semiconductor device that may solve the problems mentioned above.

### SUMMARY

A semiconductor device includes an active layer having an active region, a source electrode and a drain electrode disposed on the active region of the active layer and extending along a first direction, a source metal layer disposed on the active region and electrically connected to the source electrode, a drain metal layer disposed on the active region and electrically connected to the drain electrode, and a source pad disposed on the active region. The source metal layer extends along a second direction and has a trapezoid shape in a plan view. The drain metal layer extends along the second direction and has a trapezoid shape in the plan view. The source pad is electrically connected to the source metal layer, and the source pad includes a body portion extending along a first direction and a branch portion extending along the second direction.

A semiconductor device includes an active layer having an active region, a source electrode and a drain electrode disposed on the active region of the active layer and extending along a second direction, a source metal layer disposed on the active region and electrically connected to the source electrode, a drain metal layer disposed on the active region and electrically connected to the drain electrode, and a source pad disposed on the active region, wherein the source pad is electrically connected to the source metal layer. The source metal layer extends along a second direction. The drain metal layer extends along the second direction. The source pad includes a body portion extending along a first direction and a branch portion extending along the second direction. A first width along the first direction of the source metal layer is smaller than a second width along the first direction of the branch portion of the source pad overlapping the source metal layer in the plan view.

In the aforementioned embodiments, since the source pad and the drain pad has a trapezoid shape, the parasitic on-state resistance and the current density of the source pad and the drain pad can be reduced. Since the source metal layer and the drain metal layer has a trapezoid shape and is narrower than the drain pad and the source pad, the overall capacitance of the semiconductor device 100 can be reduced. Since the first vias and the second vias in the top insulating layer are arranged as two rows along a second direction and are alternatively arranged along the first directions such that the wire density is increased and the parasitic on-state resistance is reduced.

### BRIEF DESCRIPTION OF THE DRAWINGS

FIG. 1A is a top view of a semiconductor device according to some embodiments of the present disclosure.

FIG. 1B is a top view of the semiconductor device of FIG. 1A, and the source pad and the drain pad are omitted.

FIG. 2A is a cross-sectional view along line 2A-2A of FIG. 1.

FIG. 2B is a cross-sectional view along line 2B-2B of FIG. 1.

FIG. 3 is a semiconductor device according to another embodiment of the present disclosure.

FIG. 4 is a top view of a semiconductor device according to another embodiment of the present disclosure.

FIG. 5 is a cross-sectional view taken along line 5-5 of FIG. 4.

FIG. 6 is a top view of the semiconductor device in FIG. 4 connected with a leadframe according to one embodiment of the present disclosure.

FIG. 7 is a cross-sectional view of the semiconductor device in FIG. 4 connected with a leadframe according to another embodiment of the present embodiment.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

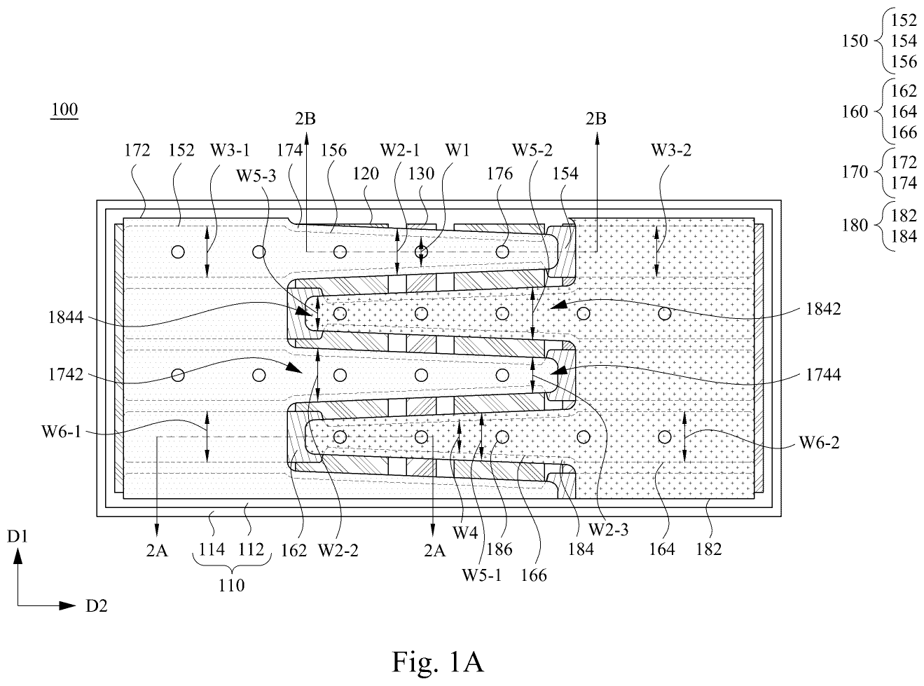

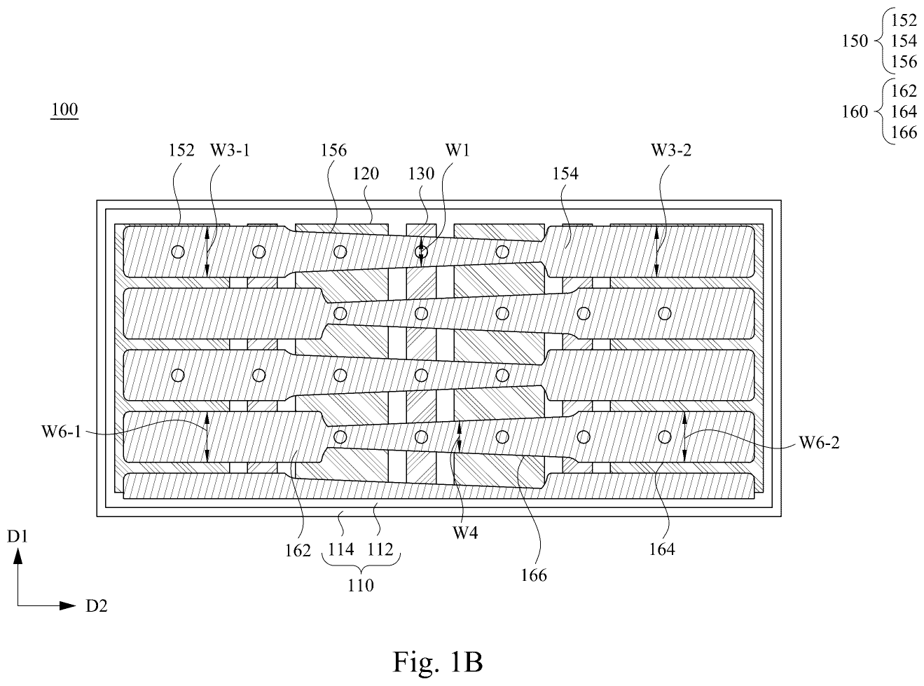

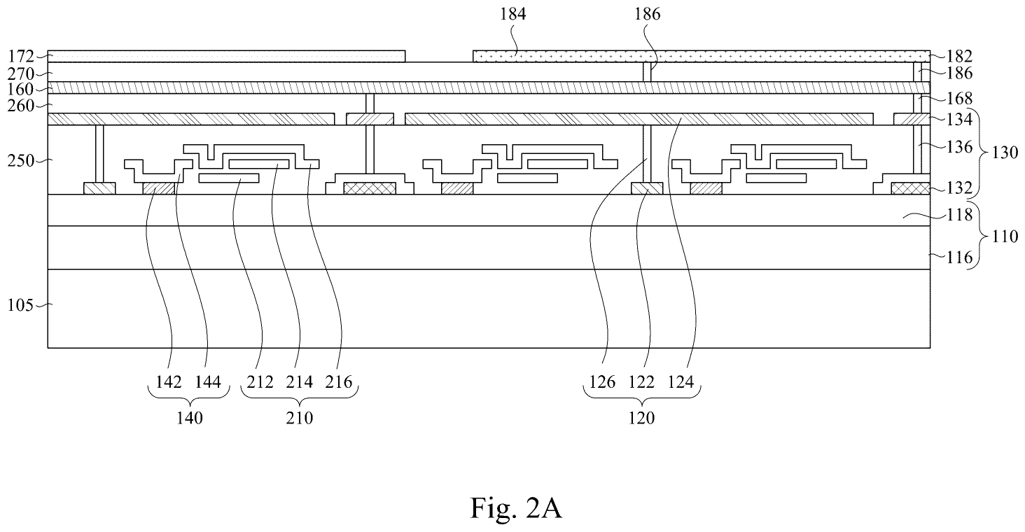

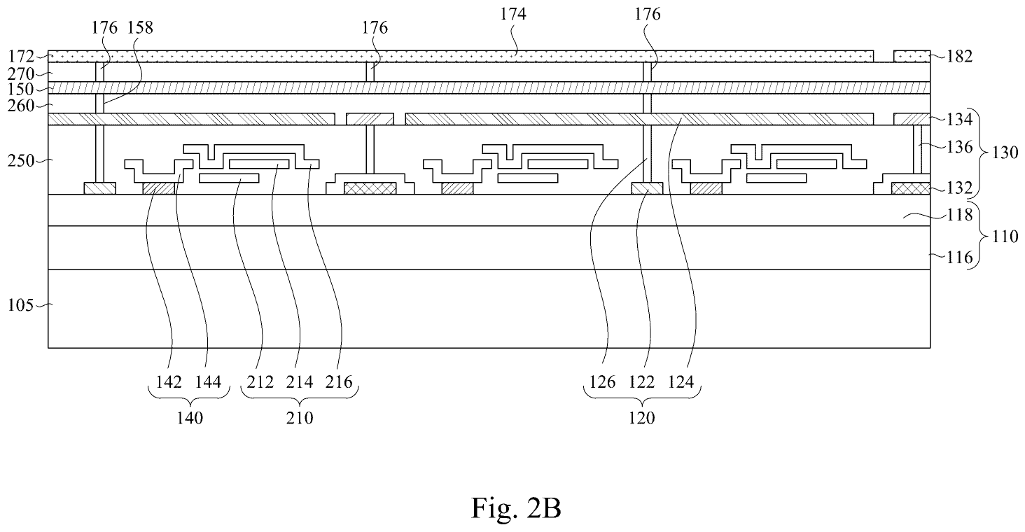

FIG. 1A is a top view of a semiconductor device 100 according to some embodiments of the present disclosure. FIG. 1B is a top view of the semiconductor device of FIG. 1, and the source pad and the drain pad are omitted. FIG. 2A is a cross-sectional view along line 2A-2A of FIG. 1A, and FIG. 2B is a cross-sectional view along line 2B-2B of FIG. 1A. Reference is made to FIGS. 1, 2A, and 2B. The semiconductor device 100 includes an active layer 110, source electrodes 120, drain electrodes 130, gate electrodes 140, source metal layers 150, drain metal layers 160, a source pad 170, and a drain pad 180. The active layer 110 has an active region 112. The source electrodes 120, the drain electrodes 130, the gate electrodes 140, the source metal layers 150, and the drain metal layers 160 are disposed on the active region 112 of the active layer 110.

The source metal layers 150 and the drain metal layers 160 are alternately arranged along a first direction D1 and extend along a second direction D2 different from the first direction D1. For example, the first direction D1 is substantially perpendicular to the second direction D2 as shown in FIG. 1A. The source metal layers 150 are spaced from each other, and the drain metal layers 160 are spaced from each other. The term “substantially” as used herein may be applied to modify any quantitative representation which could permissibly vary without resulting in a change in the basic function to which it is related.

The source metal layers 150 and the drain metal layers 160 have a trapezoid shape in a plan view. In the present embodiment, the source metal layers 150 and the drain metal layers 160 only partially have the trapezoid shape.

Specifically, each of the source metal layers 150 includes a first body portion 152, a second body portion 154, and a branch portion 156. The body portion 172 of the source pad 170 overlaps the first body portion 152 in the plan view, and the first body portions 152 have a rectangular shape. The second body portion 154 overlaps the body portion 182 of the drain pad 180 in the plan view, and the second body portions 154 have a rectangular shape. The branch portions 156 connect the first body portion 152 and the second body portion 154 in the plan view, and the branch portions 156 have the trapezoid shape. In some other embodiments, the first body portion 152 and the second body portion 154 have other shapes such as the trapezoid shape.

Similarly, each of the drain metal layers 160 includes a first body portion 162, a second body portion 164, and a branch portion 166. The body portion 172 of the source pad 170 overlaps the first body portion 162 in the plan view, and the first body portions 162 have a rectangular shape. The body portion 182 of the drain pad 180 overlaps the second body portion 164 in the plan view, and the second body portions 164 have a rectangular shape. The branch portions 166 connect the first body portion 162 and the second body portion 164 in the plan view, and the branch portions 166 have the trapezoid shape. In some other embodiments, the first body portion 162 and the second body portion 164 have other shapes such as the trapezoid shape.

The source pad 170 includes a body portion 172 extending along the first direction D1 and multiple branch portions 174 extending along the second direction D2. The source pad 170 is electrically connected to the source metal layers 150 and the source electrodes 120. The drain pad 180 includes a body portion 182 extending along the first direction D1 and multiple branch portions 184 extending along the second direction D2. The drain pad 180 is electrically connected to the drain metal layer 160 and the drain electrodes 130.

The body portion 172 of the source pad 170 and the body portion 182 of the drain pad 180 have rectangular shape. That is, the source pad 170 and the drain pad 180 are substantially parallel to each other. The branch portions 174 of the source pad 170 and the branch portions 184 of the drain pad 180 each has a trapezoid shape in the plan view. As shown in FIG. 1A, the branch portions 174 of the source pad 170 substantially overlap the portions of the source metal layers 150 that have a trapezoid shape. The branch portions 184 of the drain pad 180 substantially overlap the portions of the drain metal layers 160 that have a trapezoid shape. In some other embodiments, the body portion 172 of the source pad 170 and the body portion 182 of the drain pad 180 have other shapes such as the trapezoid shape.

In the present embodiment, a first width W1 along the first direction D1 of the branch portions 156 of source metal layers 150 is smaller than a second width W2-1 along the first direction D1 of the branch portions 174 of the source pad 170. That is, the trapezoid shaped portions of the source metal layers 150 are narrower than the branch portions 174 of the source pad 170, and an area of the branch portions 156 of source metal layers 150 is smaller than an area of the branch portions 174 of the source pad 170.

The width W2-2 of a first side 1742 of the branch portions 174 of the source pad 170 close to the body portion 172 of the source pad 170 is greater than a width W2-3 of a second side 1744 of the branch portion 174 of the source pad 170 away from the body portion 172 of the source pad 170. That is, the width of the branch portions 174 of the source pad 170 gradually decreases along the second direction D2. Specifically, the current at the second side 1744 (i.e., the tail part) is smaller than the current at the first side 1742 (i.e., the root part). Therefore, a wider first side 1742 can increase the area of the root part and reduce the parasitic on-state resistance of the source pad 170. A narrower second side 1744 can reduce the overall current density of the source pad 170.

The first body portions 152 of the source metal layers 150 have a third width W3-1 along the first direction D1, and the first width W1 of the branch portions 156 are smaller than the third width W3-1. In the present embodiment, the second body portion 154 has a third width W3-2, and the third width W3-1, W3-2 can be the same or different. That is, the trapezoid shaped portions of the source metal layers 150 are narrower than the rectangular shaped portions of the source metal layers 150.

Similarly, a fourth width W4 along the first direction D1 of the branch portions 166 of the drain metal layers 160 is smaller than a fifth width W5-1 along the first direction D1 of the branch portions 184 of the drain pad 180. That is, the trapezoid shape portions of the drains metal layers 160 are narrower than the branch portions 184 of the drain pad 180, and an area of the branch portions 166 of the drain metal layers 160 is smaller than an area of the branch portions 184 of the drain pad 180.

The width W5-2 of a first side 1842 of the branch portions 184 of the drain pad 180 close to the body portion 182 of the drain pad 180 is greater than the width W5-3 of a second side 1844 of the branch portions 184 of the drain pad 180 away from the body portion 182 of the drain pad 180. That is, the width of the branch portions 184 of the drain pad 180 gradually increases along the second direction D2. Specifically, the current at the second side 1844 (i.e., the tail part) is smaller than the current at the first side 1842 (i.e., the root part). Therefore, a wider first side 1842 can increase the area of the root part and reduce the parasitic on-state resistance of the drain pad 180. A narrower second side 1844 can reduce the overall current density of the drain pad 180.

The first body portions 162 of the drain metal layers 160 have a sixth width W6-1 along the first direction D1, and the fifth width W5-1 of the branch portions 166 are smaller than the sixth width W6-1. In the present embodiment, the second body portion 164 has a sixth width W6-2, and the sixth width W6-1, W6-2 can be the same or different. That is, the trapezoid shaped portions of the source metal layers 150 are narrower than the rectangular shaped portions of the source metal layers 150.

Reference is made to FIG. 1A. The active layer 110 further includes an insulating region 114 surrounding the active region 112. The insulating region 114 may be formed by implanting ions, such as oxygen, nitrogen, carbon, or the like, into the active layer 110. In some other embodiments, the insulating region 114 is a shallow trench isolation (STI). The active layer 110 may be selectively disposed on a substrate 105. Reference is made to FIGS. 2A and 2B. In some embodiments, the active layer 110 includes a channel layer 116 and a barrier layer 118 disposed on the channel layer 116. In some embodiments, the channel layer 116 can be made of GaN, and the barrier layer 118 can be made of AlGaN.

The semiconductor device 100 further includes a dielectric layer 270. For clarity, the dielectric layer 270 is merely illustrated in FIGS. 2A and 2B. The dielectric layer 270 covers the source metal layers 150 and the drain metal layers 160. The source pad 170 and the drain pad 180 are disposed on the dielectric layer 270. The source pad 170 is electrically connected to the source metal layers 150, for example, through vias 176 disposed in the dielectric layer 270. The drain pad 180 is electrically connected to the drain metal layers 160, for example, through vias 168 disposed in the dielectric layer 270.

Reference is made to FIGS. 2A and 2B. In the present embodiment, the source electrodes 120 include bottom source electrode portions 122 and top source electrode portions 124. The drain electrodes 130 include bottom drain electrode portions 132 and top drain electrode portions 134. In some other embodiments, the top source electrode portion 124 and the top drain electrode portion 134 can be omitted. The gate electrodes 140 include bottom gate electrode portion 142, top gate electrode portion 144, and multiple field plates 210 electrically connected to the source electrode 120. The field plates 210 includes a first field plate 212, a second field plate 214, and a third field plate 216.

The semiconductor device 100 further includes dielectric layers 250 and 260. For clarity, the dielectric layers 250 and 260 are merely illustrated in FIGS. 2A and 2B. The dielectric layer 250 is disposed on the active layer 110. The dielectric layer 250 covers the bottom source electrode portions 122, the bottom drain electrode portions 132, and the gate electrodes 140. In other words, the bottom source electrode portions 122, the bottom drain electrode portions 132, and the gate electrodes 140 are disposed between the dielectric layer 260 and the active layer 110. The top source electrode portions 124 are disposed on the dielectric layer 250 and cover the bottom source electrode portions 122 and the gate electrodes 140, and the top drain electrode portions 134 are disposed on the dielectric layer 250 and cover the bottom drain electrode portions 132.

The dielectric layer 260 covers the top source electrode portions 124 and the top drain electrode portions 134. In other words, the top source electrode portions 124 and the top drain electrode portions 134 are disposed between the dielectric layers 260 and 250, and the source metal layers 150 and the drain metal layers 160 are disposed between the dielectric layers 260 and 270. The top source electrode portions 124 and the top drain electrode portions 134 extend along the second direction D2 and alternately arranged along the first direction D1.

The source metal layers 150 are disposed on the dielectric layer 260 and are electrically connected to the top source electrode portions 124, for example, through vias 158 disposed in the dielectric layer 260. The drain metal layers 160 are disposed on the dielectric layer 260 and are electrically connected to the top drain electrode portions 134, for example, through vias 168 disposed in the dielectric layer 260. The source metal layers 150 and the top source electrode portions 124 extend along different directions, and the drain metal layers 160 and the top drain electrode portions 134 extend along different directions.

The top source electrode portions 124 are electrically connected to the bottom source electrode portions 122, for example, through vias 126 disposed in the dielectric layer 250 and are electrically isolated from the gate electrodes 140. The top drain electrode portions 134 are electrically connected to the bottom drain electrode portions 132, for example, through vias 136 disposed in the dielectric layer 250. The top source electrode portions 124 are spaced from each other, and the top drain electrode portions 134 are spaced from each other.

Reference is made to FIG. 1A and FIG. 2A. Since the area of the branch portions 166 of the drain metal layers 160 is smaller than the area of the branch portions 184 of the drain pad 180, the overlapped area between the drain metal layers 160 and the drain pad 180 is reduced. As such, the capacitance between the drain metal layers 160 and the top source electrode portions 124 is reduced. In addition, a part of the capacitance is formed by an outer part of the branch portions 184 (i.e., the part which does not overlap the branch portions 166) and the top source electrode portions 124. Since the distance between the drain pad 180 and the top source electrode portions 124 is larger than the distance between the top source electrode portions 124 and the drain metal layers 160, the overall capacitance of the semiconductor device 100 can be reduced.

Reference is made to FIG. 1A and FIG. 2B. Since the area of the branch portions 156 of the source metal layers 150 is smaller than the area of the branch portions 174 of the source pad 170, the overlapped area between the drain metal layers 160 and the drain pad 180 is reduced. As such, the capacitance between the source metal layers 150 and the top drain electrode portion 134 is reduced. In addition, a part of the capacitance is formed by an outer part of the branch portions 174 (i.e., the part which does not overlap the branch portions 156) and the top drain electrode portions 134. Since the distance between the source pad 170 and the top drain electrode portions 134 is larger than the distance between the source metal layers 150 and the top drain electrode portion 134, the overall capacitance of the semiconductor device 100 can be reduced.

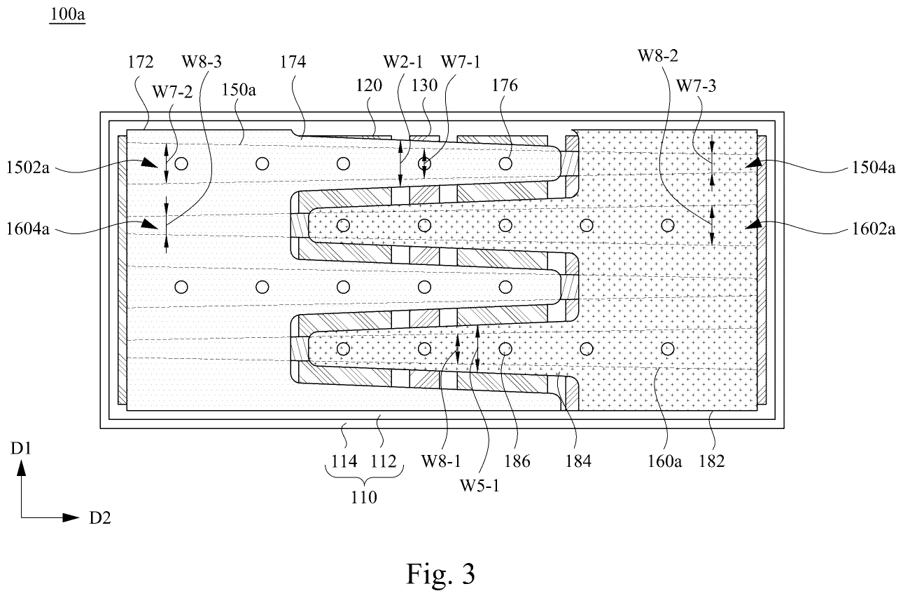

FIG. 3 is a semiconductor device 100a according to another embodiment of the present disclosure. The semiconductor device 100a is similar to the semiconductor device 100 in FIG. 1A, and the difference is the configuration of the source metal layers 150a and the drain metal layers 160a. The source metal layers 150a does not include rectangular shaped portion. Therefore, as shown in FIG. 3, the width of the source metal layers 150a along the second direction D2 gradually decreases along the first direction D1. In other words, the width W7-2 of a first side 1502a of the source metal layers 150a below the body portion 172 of the source pad 170 is greater than the width W7-3 of a second side 1504a of the source metal layers 150a below the body portion 182 of the drain pad 180.

The relationship between the width of the branch portions 174 of the source pad 170 and the source metal layers 150a are similar to which described in the embodiment shown in FIG. 1A. A seventh width W7-1 along the second direction D2 of the portions of the source metal layers 150 under the branch portions 174 of the source pad 170 is smaller than the second width W2-1 along the second direction D2 of the branch portions 174 of the source pad 170. As described above, such structural design can reduce the overall capacitance of the semiconductor device 100a.

The drain metal layers 160a does not include rectangular shaped portion. Therefore, the width of the drain metal layers 160a gradually increases along the first direction D1. In other words, the width W8-2 of a first side 1602a of the drain metal layers 160a below the body portion 182 of the drain pad 180 is greater than the width W8-3 of a second side 1604a of the drain metal layers 160a below the body portion 172 of the source pad 170.

The relationship between the width of the branch portions 184 of the drain pad 180 and the drain metal layers 160a are similar to which described in the embodiment shown in FIG. 1A. An eighth width W8-1 along the second direction D2 of the portions of the drain metal layers 160 under the branch portions 184 of the drain pad 180 is smaller than the fifth width W5-1 along the second direction D2 of the branch portions 184 of the drain pad 180. As described above, such structural design can reduce the overall capacitance of the semiconductor device 100a.

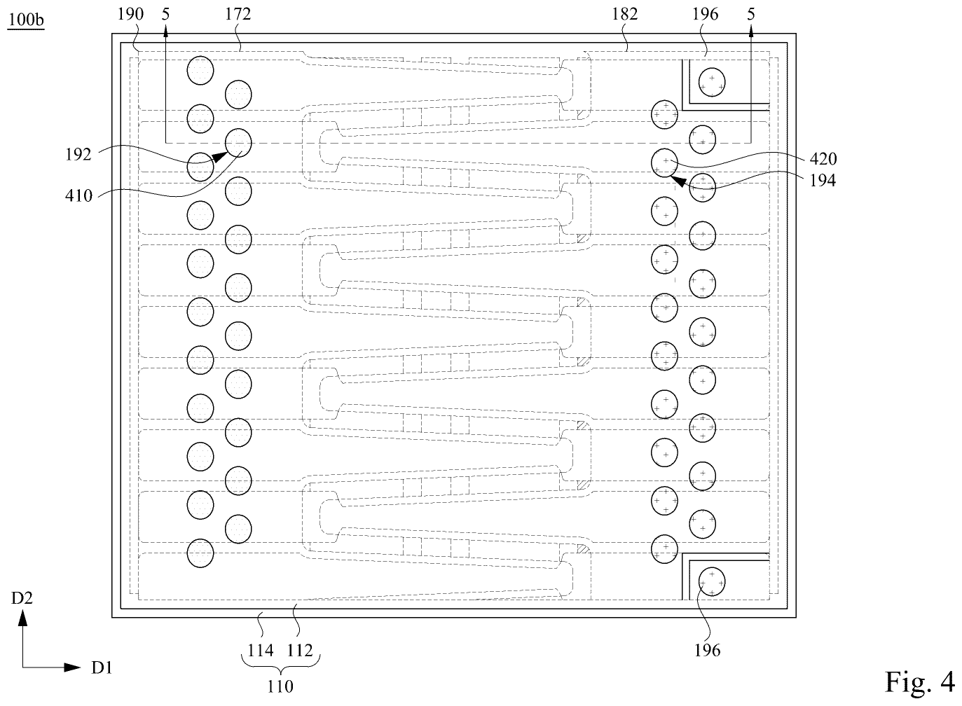

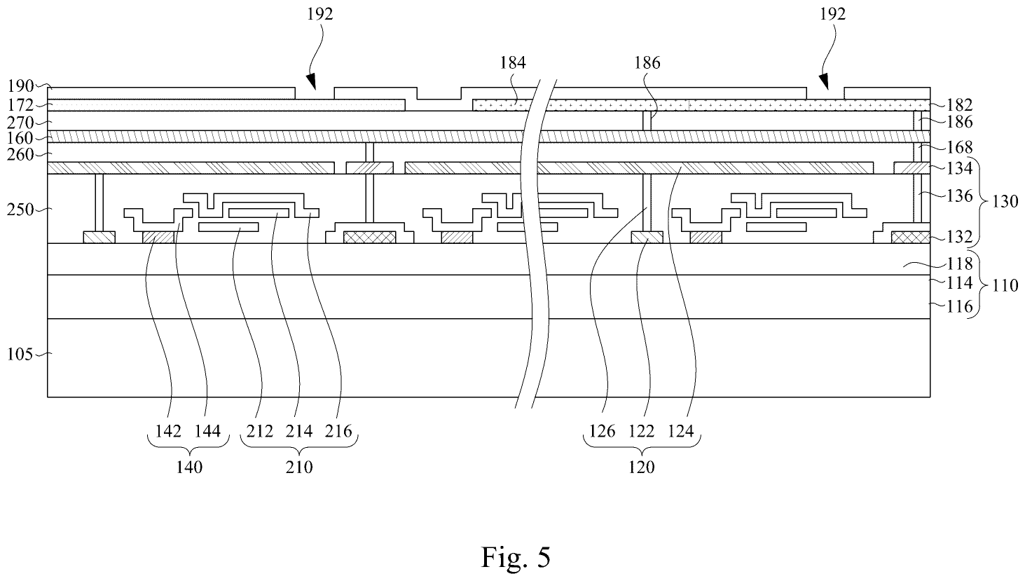

FIG. 4 is a top view of a semiconductor device 100b according to another embodiment of the present disclosure. FIG. 5 is a cross-sectional view taken along line 5-5 of FIG. 4. Reference is made to FIG. 4 and FIG. 5. The semiconductor device 100b further includes a top insulating layer 190 disposed above the source pad 170 and the drain pad 180. Multiple first through holes 192 are formed in the top insulating layer 190 to expose the source pad 170. The first through holes 192 are arranged as two rows along the first direction D1. Multiple second through holes 194 are formed in the top insulating layer 190 to expose the drain pad 180. The second through holes 194 are arranged as two rows along the first direction D1. The semiconductor device 100b includes two gate electrodes disposed on the active region 112 of the active layer 110 and arranged along the second direction D2. Two third through holes 196 are formed in the top insulating layer 190 for interconnecting the two gates.

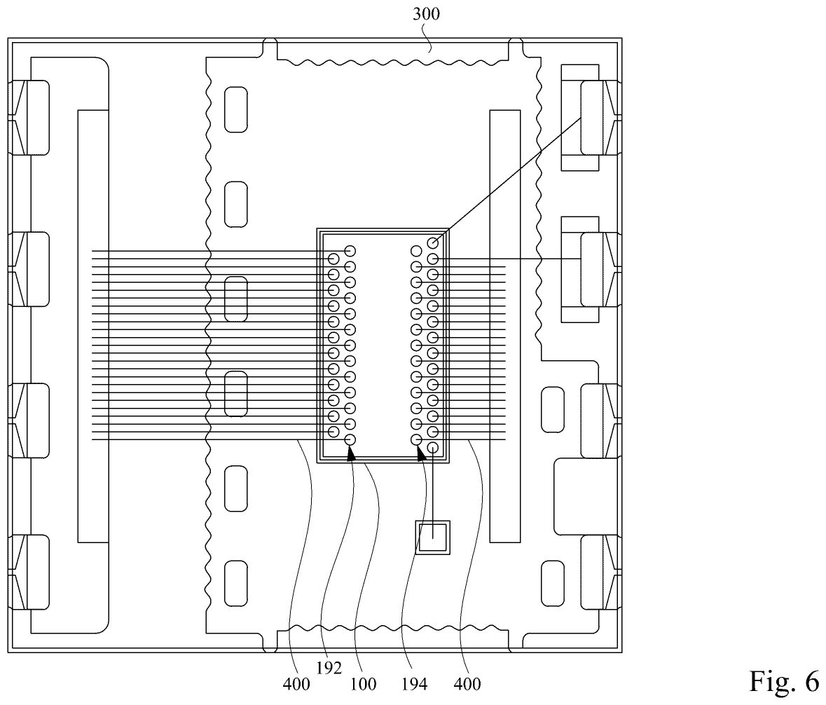

FIG. 6 is a top view of the semiconductor device 100b in FIG. 4 connected with a leadframe 300 according to one embodiment of the present disclosure. In the present embodiments, first vias 410 are formed in the first through holes 192 and overlaps the source pad 170. The first vias 410 are arranged as two rows along the first direction D1. Second vias 420 are formed in the second through holes 194 and overlaps the drain pad 180. The second vias 420 are arranged as two rows along the first direction D1.

The first vias 410 and the second vias 420 are connected with wires 400, and the semiconductor device 100b and the leadframe 300 are electrically connected through the wires 400. The first vias 410 and the second vias 420 are alternatively arranged along the second directions D2 such that the wire density is increased and the parasitic on-state resistance is reduced.

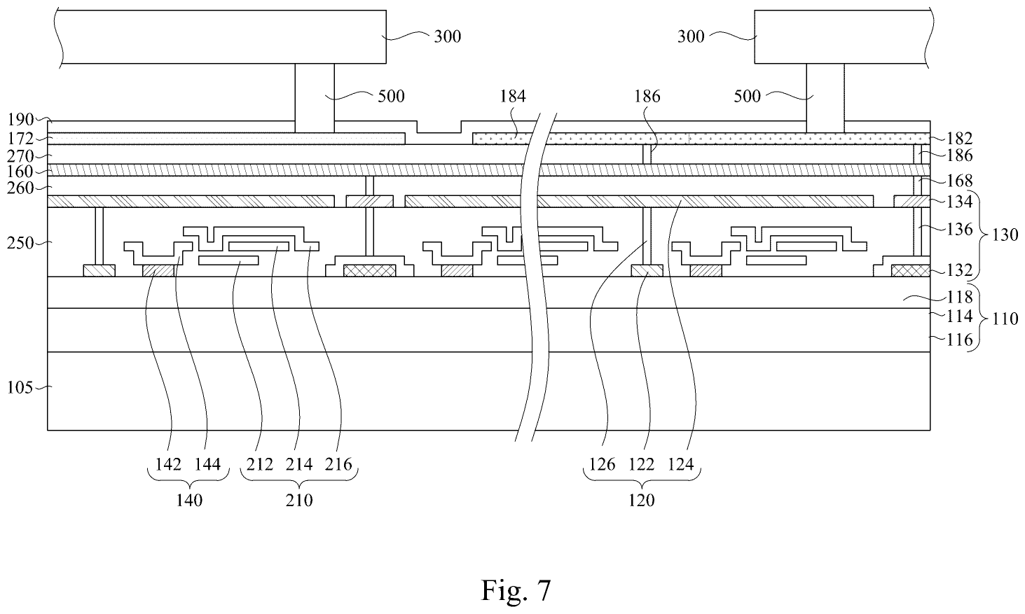

FIG. 7 is a cross-sectional view of the semiconductor device 100b in FIG. 4 connected with a leadframe 300 according to another embodiment of the present embodiment. In the present embodiments, multiple pillars 500 are formed in the first through holes 192 and the second through holes 194. The pillars 500 extend from the top insulating layer 190 and connect the leadframe 300 by using flip chip process.

In summary, since the source pad and the drain pad has a trapezoid shape, the parasitic on-state resistance and the current density of the source pad and the drain pad can be reduced. Since the source metal layer and the drain metal layer has a trapezoid shape and is narrower than the drain pad and the source pad, the overall capacitance of the semiconductor device 100 can be reduced. Since the first vias and the second vias in the top insulating layer are arranged as two rows along a first direction and are alternatively arranged along the second directions such that the wire density is increased and the parasitic on-state resistance is reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A semiconductor device, comprising:
an active layer having an active region;
a source electrode and a drain electrode disposed on the active region of the active layer and extending along a first direction;
a source metal layer disposed on the active region and electrically connected to the source electrode, wherein the source metal layer extends along a second direction and has a trapezoid shape in a plan view;
a drain metal layer disposed on the active region and electrically connected to the drain electrode, wherein the drain metal layer extends along the second direction and has a trapezoid shape in the plan view; and
a source pad disposed on the active region, wherein the source pad is electrically connected to the source metal layer, wherein the source pad comprises a body portion extending along a first direction and a branch portion extending along the second direction.

2. The semiconductor device of claim 1, wherein the branch portion of the source pad has a trapezoid shape in the plan view.

3. The semiconductor device of claim 1, wherein a first width of the source metal layer along the first direction is smaller than a second width of the branch portion of the source pad along the first direction overlapping the source metal layer in the plan view.

4. The semiconductor device of claim 1, wherein the source metal layer comprises:
a first body portion, wherein the body portion of the source pad overlaps the first body portion in the plan view;
a second body portion, wherein the body portion of the drain pad overlaps the second body portion in the plan view, wherein the second body portion has rectangular shape; and
a branch portion connecting the first body portion and the second body portion, wherein the branch portion has the trapezoid shape in the plan view.

5. The semiconductor device of claim 4, wherein the first body portion has a rectangular shape.

6. The semiconductor device of claim 4, wherein the first body portion of the source metal layer has a third width along the first direction, the branch portion of the source metal layer has a fourth width along the first direction smaller than the third width.

7. The semiconductor device of claim 1, further comprising:
a drain pad disposed on the active region, wherein the drain pad is electrically connected to the drain metal layer, and the drain pad comprises a body portion extending along the first direction and a branch portion extending along the second direction in the plan view.

8. The semiconductor device of claim 7, wherein the branch portion of the drain pad has a trapezoid shape in the plan view.

9. The semiconductor device of claim 7, wherein a fifth width of the drain metal layer along the first direction is smaller than a sixth width of the branch portion of the drain pad along the first direction overlapping the drain metal layer in the plan view.

10. The semiconductor device of claim 7, wherein the drain metal layer comprises:
a first body portion, wherein the body portion of the source pad overlaps the first body portion in the plan view, wherein the first body portion of the drain metal layer has a rectangular shape;
a second body portion, wherein the body portion of the drain pad overlaps the second body portion in the plan view; and
a branch portion connecting the first body portion and the second body portion, wherein the branch portion of the drain metal layer has the trapezoid shape in the plan view.

11. The semiconductor device of claim 10, wherein the second body portion of the drain metal layer has a rectangular shape.

12. The semiconductor device of claim 10, wherein the first body portion of the drain metal layer has a seventh width along the first direction, the branch portion has an eighth width along the first direction smaller than the seventh width.

13. The semiconductor device of claim 1, further comprising:
two gate electrodes disposed on the active region of the active layer and arranged along the first direction.

14. The semiconductor device of claim 7, further comprising:
a top insulating layer disposed above the source pad and the drain pad;
a plurality of first through holes in the top insulating layer and overlapping the source pad, wherein the first through holes are arranged as two rows in the second direction; and
a plurality of second through holes in the top insulating layer and overlapping the drain pad, wherein the second through holes are arranged as two rows in the second direction, and the source pad and the drain pad are exposed from the top insulating layer through the first through holes and the second through holes.

15. The semiconductor device of claim 14, further comprising:
a leadframe;
a plurality of first vias in the first through holes;
a plurality of second vias in the second through holes; and
a plurality of wires connecting the first vias, the second vias, and the leadframe.

16. The semiconductor device of claim 14, further comprising:
a leadframe; and
a plurality of pillars in the top insulating layer and connecting the leadframe.

17. A semiconductor device, comprising:
an active layer having an active region;
a source electrode and a drain electrode disposed on the active region of the active layer and extending along a first direction;
a source metal layer disposed on the active region and electrically connected to the source electrode, wherein the source metal layer extends along a second direction;
a drain metal layer disposed on the active region and electrically connected to the drain electrode, wherein the drain metal layer extends along the second direction; and
a source pad disposed on the active region, wherein the source pad is electrically connected to the source metal layer, the source pad comprises a body portion extending along a first direction and a branch portion extending along the second direction, and a first width of the source metal layer along the first direction is smaller than a second width of the branch portion of the source pad along the first direction overlapping the source metal layer in a plan view.

18. The semiconductor device of claim 17, wherein at least one of the source metal layer, the drain metal layer, and the branch portion of the source pad has a trapezoid shape in a plan view.

19. The semiconductor device of claim 17, wherein a third width of a first side of the branch portion of the source pad close to the body portion of the source pad is greater than a fourth width of a second side of the branch portion of the source pad away from the body portion of the source pad.

20. The semiconductor device of claim 17, wherein a fifth width of a first side of the source metal layer below the body portion of the source pad is greater than a sixth width of a second side of the source metal layer away from the body portion of the source pad.

21. The semiconductor device of claim 17, further comprising:
a drain pad disposed on the active region, wherein the drain pad is electrically connected to the drain metal layer, the drain pad comprises a body portion extending along the first direction and a branch portion extending along the second direction in the plan view, and wherein a seventh width of a first side of the branch portion of the drain pad close to the body portion of the drain pad is greater than an eighth width of a second side of the branch portion of the drain pad away from the body portion of the drain pad.

22. The semiconductor device of claim 17, wherein a ninth width of a first side of the drain metal layer below the body portion of the drain pad is greater than a tenth width of a second side of the drain metal layer below the body portion of the source pad.
